(19) United States
(12) Patent Application Publication
(10) Pub. No.: US 2007/0158661 A1
(43) Pub. Date: Jul. 12, 2007

(54) ZnO nanostructure-based light emitting device

(75) Inventors: Yicheng Lu, East Brunswick, NJ (US); Jian Zhong, Edison, NJ (US)

Correspondence Address: HOFFMANN & BARON, LLP, 6900 JERICHO TURNPIKE, SYOSSET, NY, 11791, US

(73) Assignee: RUTGERS, The State University of New Jersey

(21) Appl. No.: 11/330,669

(22) Filed: Jan. 12, 2006

(51) Int. Cl. H01L 33/00

(52) U.S. Cl. 257/79

(57) ABSTRACT

ZnO nanostructure-based LEDs are provided to improve the emission efficiency. The devices include several configurations. Single crystal ZnO or MgₓZn₁₋ₓO nanotips are grown on the top of a GaN p-n junction. Also, n-type ZnO nanotips are grown on p-GaN film to form an n-type ZnO nanotip/p-GaN heterojunction LED. A ZnO LED can be formed when depositing n-type ZnO nanotips on a p-type ZnO film layer. The ZnO nanotips, with a p-n junction in the tips, can be grown on glass for a low cost nano-LED, and can be grown on Si substrates to form an integrated ZnO nanoLED array on Si chips.

This invention was made with partial Government support under Grant No. NSF CCR-0103096, awarded by the National Science Foundation. Therefore, the Government has certain rights in this invention.

### FIELD OF THE INVENTION

This invention relates generally to Light Emitting Diode (LED) technology, and pertains more particularly to high quantum efficiency LEDs based on zinc oxide (ZnO) nanostructures for UV, blue, and white applications.

### BACKGROUND OF THE INVENTION

UV/blue light emitting devices have a wide variety of military and civilian applications, including new solid light sources to save energy, non-line-of-sight (NLOS) covert communication, next-generation high-density optical storage, display, space communication, as well as biological and chemical detection. All require high efficient emitters. In particular, the higher the power intensity, the farther the NLOS transceivers can be placed apart. In a light emitting device, emission efficiency and low cost are paramount importance.

The emerging wide bandgap semiconductors, such as GaN and ZnO, have broad applications in UV photonics for information processing with much higher storage density and faster speed in comparison to the visible and infrared wavelength. Other important applications of UV photonics include biological agent detection as most biological agents have characteristic luminescence or absorption spectrum under UV excitation. The most important and imminent application of wide bandgap semiconductors is the new solid state light source. Compared to traditional incandescent bulbs, solid state lighting (SSL) has dramatically enhanced electrical-to-optical energy conversion efficiency.

GaN based materials have become the primary wide bandgap semiconductors for optoelectronics, particularly in blue LEDs and lasers. GaN is also attractive for high temperature and high power electronic devices. In spite of these developments, several challenges remain for GaN technology, such as a relatively high density of defects in GaN films for laser applications, difficult and high temperature deposition processes, non-availability of large size bulk crystals, and difficulty in wet chemical etching. Furthermore, it is difficult to grow and pattern GaN nanostructures.

The main technical challenge remaining for nitride LEDs is the improvement of quantum efficiency. Only ˜4% of the internal light can be extracted, which is limited by inherent loss, such as parasitic absorption during photon recyling and the narrow escape cone. Much effort has been made to improve light extraction efficiency in GaN LEDs. The difficulties in manipulating a GaN LED are due to its typically p-side-up structure, as Mg dopant has a memory effect, and p-GaN is usually high resistive and undesirable to grow thick. To overcome these problems, an excimer laser was previously used to lift off the as-grown GaN LED from sapphire, which was bonded to a metal surface using Van der Waals forces, and the flipped n-GaN layer was photoelectrochemically etched for surface roughing [T. Fujii et al (2004), Appl. Phys. Lett. 84, p.855]. Other research efforts have included the growth of a tunneling junction consisting of narrow band InGaN on top of p-GaN, and a sequentially grown n-GaN layer, which served as the template whereby GaN PCs were fabricated [T. N. Oder et al. (2004), Appl. Phys. Lett. 84, p.466]. However, laser lift off and Van der Waals bonding technologies are very complicated. On the other hand, the employment of a tunneling junction could degrade the device's electrical and optical properties.

Zinc oxide (ZnO) is emerging as a wide bandgap (˜3.3 eV at room temperature) semiconductor. Compared with GaN, ZnO has several advantages: (i) its free exciton binding energy (60 meV) is much higher; (ii) a large size native substrate is available commercially; (iii) wet chemical processing is feasible; (iv) epitaxial films can be grown below 400° C.; (v) it shows higher radiation hardness; and (vi) ZnO nanostructures can be grown on various substrates at low temperatures. Despite these advantages, the development of ZnO based devices, such as LED, is still in the research stage, due to the difficulty in making a quality device using controllable and reproducible p-type doping. The difficulties of p-type doping in ZnO have been ascribed to: 1) oxygen vacancies and/or zinc interstitials acting as donors; 2) hydrogen is a shallow donor that activates oxygen vacancies and neutralizes acceptors; 3) compensation effect from native point defects, resulting in passivation of acceptors; 4) low solubility for dopant; and 5) lattice relaxation drives energy levels to deep within the gap. Recently, a breakthrough of p-type doping ZnO has been achieved. A hole concentration of 2×10²⁰ cm⁻³ and a Hall mobility of 8 cm²V⁻¹S⁻¹ were obtained using nitrogen doping, and a ZnO homojunction LED has been demonstrated [Tsukazaki et al. (2005), Nature Mater. 4, p. 42].

Epitaxial ZnO films can be grown on GaN, as the lattice mismatch between GaN and ZnO is relatively small. Table 1 below lists the crystal structure and lattice parameters of ZnO, GaN, AIN and sapphire (Al₂O₃). The small lattice mismatch between ZnO and GaN (in-plane mismatch 2%) ensures a lower defect density, compared to ZnO grown on sapphire. The band alignment of ZnO/GaN heterostructures has been investigated for hybrid opto-electronic devices [S. K. Hong et al. (2003), Appl. Phys. Lett. 78, p.3349]. A Type-II band alignment was reported, with the valence band maximum of GaN above that of ZnO. The band offsets, Ev, ranged between 0.6 eV to 1.0 eV, depending on the GaN surface preparation. Hybrid devices reported to date include the use of ZnO as a transparent conductive oxide electrode for GaN [K. Nakahara et al (2004), Jp-n. J. Appl. Phys. Part 2, 43, L180], and n-ZnO/p-GaN heterojunction LEDs [Y. I. Alivov et al. (2004), Appl. Phys. Lett., 83, p.2943].

TABLE 1
Crystal Structure and lattice parameters of ZnO, AlN, GaN and Al₂O₃

| Crystal | Structure | Lattice Parameter (Å) | |
|---|---|---|---|
| ZnO | Wurtzite (hexagonal) | a = 3.249 | c = 5.206 |
| AlN | Wurtzite (hexagonal) | a = 3.11 | c = 4.98 |
| GaN | Wurtzite (hexagonal) | a = 3.189 | c = 5.185 |
| Al₂O₃ | Corundum (rhombohedral, | a = 4.758 | c = 12.992 |
| | hexagonal packing of oxygen | | |
| | ions) | | |

Semiconductor nanowires and nanotips have attracted extensive attention due to their dramatically enhanced electron-hole interaction from a reduced dimensionality. ZnO nanotips have been grown on various substrates including Si, glass, and c-sapphire at low temperature (˜400° C.) by metalorganic chemical vapor deposition (MOCVD) via a catalyst-free self-nucleation growth [S. Muthukumar et al. (2003), IEEE Trans. Nanotech, 261, p.50][J. Zhong et al. (2004), TMS & IEEE J. Elec. Mater., 33, p.654 ][Hanhong Chen et al. (2004), Proceedings of SPIE, Volume: 5592-31]. ZnO nanotips show excellent optical properties, such as dominant free excitonic emission at room temperature. By incorporating ZnO nanotips into an LED structure, the strong surface scattering of ZnO nanowires will randomize the angular distribution of photons, and an enlarged equivalent escape cone for the trapped photons can be achieved, leading to high external efficiency for LEDs.

This invention addresses a novel approach to use ZnO nanotips to improve quantum efficiency and realize high brightness UV/blue light emitting devices. Compared with current III-V nitride based LED technology, the inventive novel ZnO nanostructure-based light emitting devices have higher emission efficiency; they are easy to fabricate; and they are compact and of low cost. Furthermore, the inventive light emitting devices can be built on inexpensive substrates, such as glass and silicon.

### SUMMARY OF THE INVENTION

The present invention provides UV & blue Light Emitting Diodes (LEDs) based on zinc oxide (ZnO) nanostructures. In the present invention, the ZnO nanostructures grow on top of an existing GaN or ZnO LED as light extraction layer, or grow on top of a p-type GaN or ZnO layer to serve as an n-type layer to form nano-ZnO/GaN heterojunction LED or nanoZnO/epi-ZnO homojunction LED. In comparison with the conventional LEDs, the inventive ZnO nanostructured LEDs have improved emission efficiency. This results from the strong surface scattering which will randomize the angular distribution of photons inside the LED and an enlarged equivalent escape cone, leading to a high light extraction for the trapped photons. The dimension and aspect ratio of ZnO nanotips can be varies through control of growth conditions. The energy band, therefore transmission spectrum, can also be tuned by introducing dopants, such as Mg, to form MgₓZn₁₋ₓO nanotips. Such ZnO nanostructured LEDs are easy to fabricate, are compact, and of low cost.

The present invention provides an LED including a substrate; and at least one semiconductor film layer of ZnO or GaN deposited on the substrate. This LED further includes an array of nanotips made from ZnO or its ternary compound, such as MgₓZn₁₋ₓO. The nanotip array is grown either directly or indirectly on a surface of the at least one semiconductor film layer of ZnO or GaN. The LED also includes at least one transparent and conductive oxide (TCO) layer deposited on the at least one semiconductor film layer or on the nanotip array. Moreover, the LED includes a pair of metal pads. A metal pad from the pair is deposited on each of the TCO layer and the at least one semiconductor film layer of ZnO or GaN.

The present invention provides an LED, which is composed of n-type ZnO nanotips grown on p-type GaN film or p-type ZnO film. The n-type ZnO nanotips serve as the active layer in the p-n junction, and also as the extraction layer for high emission efficiency. The n-type ZnO nanotips can be grown on p-type GaN film, to form an n-type ZnO nanotips/p-GaN film heterojunction LED. The n-type ZnO nanotips can also be grown on p-type ZnO film, to form an n-type ZnO nanotips/p-ZnO film homojunction LED.

The present invention provides an LED, which consists of ZnO or MgₓZn₁₋ₓO nanotips grown on a GaN p-n junction LED or on a ZnO p-n junction LED, in which ZnO nanotips serve as a passive layer to randomize the angular distribution of light emission and enhance the extraction efficiency.

The present invention provides an LED that includes a substrate; and an array of ZnO p-n junction nanotips grown directly or indirectly on the substrate. The p-n junction in the ZnO nanotips is made up of a p-ZnO portion and an n-ZnO portion. The LED further includes an insulating material deposited on the p-n junction nanotips to fill interstices of the nanotips, a top surface of the insulator-filled nanotips being etched to form a flat surface. Also included in the LED is a TCO layer deposited on the flat top surface of the insulator-filled nanotips to serve as a top electrical contact. The LED further includes a pair of metal pads. At least one of the metal pads is deposited on the TCO layer on the nanotips.

The present invention provides ZnO nanotips based LED structures, which can be built on various substrates. The substrates include sapphire and bulk ZnO single crystal. Furthermore, glass and Si substrates can be used to build the ZnO p-n junction nanotip-based LEDs for low cost transparent optoelectronics and for integration with Si electronics, respectively.

The various embodiments will be described in further detail below.

### BRIEF DESCRIPTION OF THE DRAWINGS:

FIG. 1(a) shows ZnO nanotips grown on GaN.

FIG. 1(b) shows ZnO nanotips grown on Si.

FIG. 1(c) shows ZnO nanotips grown on glass.

FIG. 1(d) shows ZnO nanotips grown on Au.

FIG. 1(e) shows photoluminescence (PL) spectrum of ZnO nanotips, the inset shows the transmission spectrum of ZnO nanotips grown on glass.

FIG. 1(f) shows transmission electron microscope (TEM) image of a single ZnO nanotip.

FIG. 2(a) shows a θ-2θ scan of X-ray diffraction (XRD) of ZnO nanotips grown on GaN/c-Al₂O₃.

FIG. 2(b) shows the in-plane φ scan of XRD on ZnO nanotips grown on GaN/c-Al₂O₃; the φ scan is carried out along {10-13} family of ZnO planes.

FIG. 3 shows the blue light emission from an n-ZnO nanotips/p-GaN heterojunction LED.

FIG. 4(a) shows a schematic of a vertical cross-section view of a LED, which consists of a GaN p-n junction, and ZnO nanotips are grown on top of the p-GaN surface.

FIG. 4(b) shows a schematic of a vertical cross-section view of an n-ZnO nanotips/p-GaN heterojunction LED.

FIG. 4(c) shows a schematic of a vertical cross-section view of a ZnO homojunction LED with a top layer of MgₓZn₁₋ₓO nanotips.

FIG. 4(d) shows a schematic of a vertical cross-section view of an n-ZnO nanotip/p-ZnO film homojunction LED.

FIG. 5(a) shows a schematic of a vertical cross-section view of a LED structure consisting of ZnO p-n junction nanotips grown on a glass substrate.

FIG. 5(b) shows a schematic of a vertical cross-section view of a LED structure consisting of ZnO p-n junction nanotips grown on a Si substrate.

FIG. 5(c) shows a schematic of a vertical cross-section view of a LED structure consisting of ZnO p-n junction nanotips grown on a SiO₂/Si substrate.

### DETAILED DESCRIPTION OF THE INVENTION

ZnO is an emerging direct wide bandgap semiconductor. ZnO is a polar semiconductor with the (0001) planes being Zn-terminated and the (000-1) planes being O-terminated. These two crystallographic planes have opposite polarity and hence have different surface relaxation energies. This leads to a higher growth rate along the c-axis. ZnO growth results in a pillar like structure called ZnO nanotips on these semiconducting, insulating and metallic substrates, while ZnO grown on R-plane sapphire substrates results in a smooth epitaxial film. The ZnO nanotips can be grown at relatively low temperatures, giving ZnO a unique advantage over other wide bandgap semiconductor nanostructures, such as GaN and SiC.

The ZnO nanostructure based light emitter is a compact UV/V is light emitter. Such a novel LED has many advantages over the broad area LED due to its unique material characteristics and device structure. In one type presented LED configuration, the active region utilizes nanostructure that has a larger surface area, leading to higher light extraction efficiency. The 1-D nanostructure growth, unlike the 2-D epitaxial growth, is a natural growth process governed by the growth habit of the materials. This completely different growth mechanism results in essentially dislocation-free in the nanotips that is critical to achieve high internal quantum efficiency. With such a 2-D physically confined nanotip structure, 1-D carrier transportation, and thus a more efficient current injection, can be realized. Controlled localized states due to a reduced dimension are also possibly in these nanotips, leading to carrier localization and giant gain efficiency. The invention also describes the second type of LED structure in which ZnO nanotips grown on top of GaN or ZnO p-n junction structure, acting as a passive layer to enhance the light extraction.

ZnO nanotips can be grown at much lower temperatures than other wide bandgap semiconductors, particularly, GaN, which provide the way to integrate ZnO nanotips with GaN to form high emission efficiency UV or blue LEDs. ZnO nanotips can be grown on Si, which allows the integration of ZnO nanostructure based UV/vis emitter with Si IC technology. Furthermore, ZnO nanotips can be grown on glass at low temperature, providing the great advantage for a low cost LED.

We have demonstrated that ZnO nanotips can be grown on various substrates, including GaN, Si, glass, and metal, using MOCVD. Diethyl Zinc (DEZn) and oxygen were used as the Zn precursor and oxidizer, respectively, and argon was used as a carrier gas. The growth temperature ranged from 350-500° C. The detailed growth conditions of ZnO nanotips can be found elsewhere [S. Muthukumar et al. (2003), IEEE Trans. Nanotech, 261, p.50].

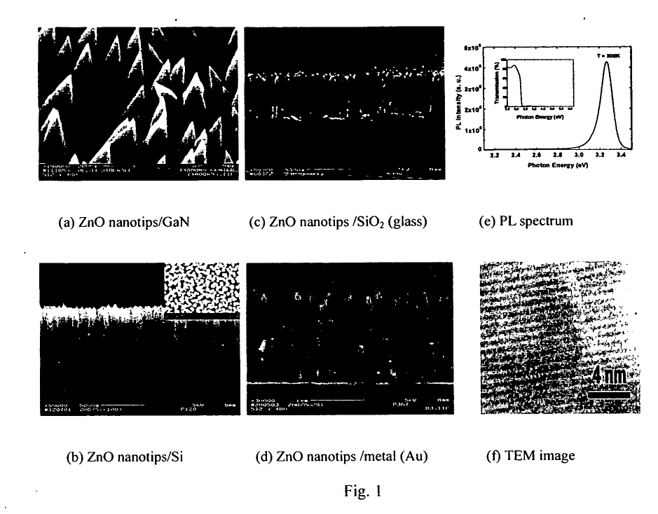

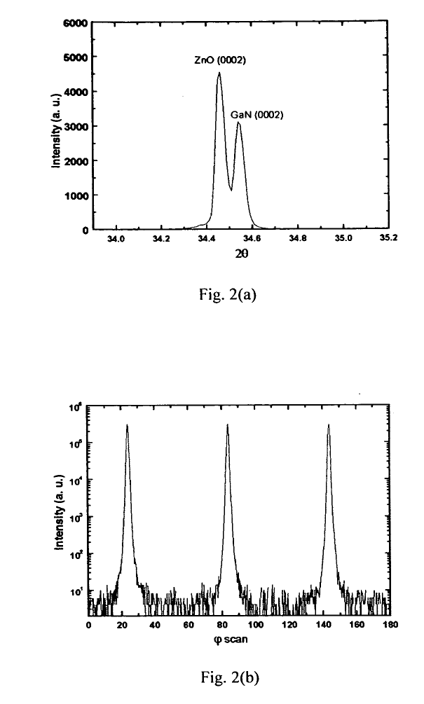

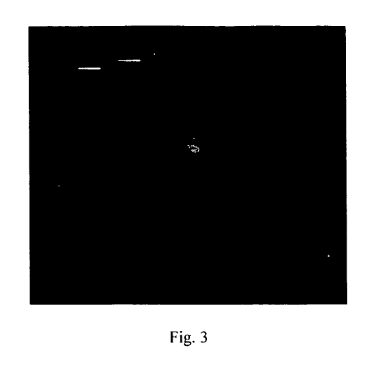

FIG. 1(a) shows a field emission scanning electron microscope (FESEM) image of ZnO nanotips grown on GaN/c-Al₂O₃ template. The ZnO nanotips are uniformly distributed over the entire GaN surface with a high density. These nanotips were found to be well oriented with the c-axis normal to the substrate surface. The nanotips have a diameter of 40-60 nm at the bottom and a height of ˜500 nm. To determine the epitaxial relationship between ZnO nanotips and GaN, X-ray diffraction (XRD) θ-2θ scan and φ scan were investigated. FIG. 2(a) shows a XRD θ-2θ scan of ZnO nanotips grown on GaN/c-Al₂O₃. Only ZnO (0002) and GaN (0002) peaks are observed, indicating that the ZnO nanotips are preferentially oriented along the c-axis, normal to the basal plane of the GaN/c-sapphire template. FIG. 2(b) shows the in-plane φ carried out along {10-13 } family of planes for ZnO. Hexagonal symmetry of ZnO can be seen from three equally spaced (60° apart) peaks in the φ scan from 0° to 180°0. The XRD patterns confirm that (10-13) ZnO ∥ (10-13) GaN, resulting in an epitaxial relationship between ZnO and GaN to be (0002) ZnO ∥ (0002) GaN and (10-10) ZnO ∥ (10-10) GaN. The formation of well-aligned ZnO nanotips on (0001) GaN substrates results from a 1-D growth governed by the growth habit of ZnO. ZnO and GaN are closely lattice matched and have the similar crystal wurtzite structure. During the initial MOCVD growth, ZnO nuclei are epitaxially grown on the GaN film uniformly. Subsequent columnar growth of ZnO nanotips is a self-assembled process due to the growth kinetics. The growth rate along the c-axis is the highest due to difference in surface relaxation energies of (0001) and (000-1) planes. Shown in FIG. 1(e) is the room temperature photoluminescence (PL) spectrum of ZnO nanotips grown on GaN. We observe a strong near band edge emission at 3.31 eV, which can be assigned to the free excitonic emission. A deep level emission band (˜2.4 eV) is not observed in these ZnO nanotips. The high optical property of ZnO nanotips grown on (0001)GaN can be attributed to low defect and dislocation density in the 1-D grown nanotips, where close lattice match and stacking order match between ZnO and GaN would lead to lower dislocation density at ZnO/GaN interface.

Recently, we have demonstrated electroluminescence from an n-ZnO nanotips/p-GaN nanoLED under forward current injection. Shown in FIG. 3 is the blue light emission of an n-ZnO nanotips/p-GaN heterojunction LED. This is the critical step that proves the technical feasibility of the invented ZnO nanotip-based LED technology.

FIG. 1(b) shows a FESEM picture of ZnO nanotips grown on Si substrate. ZnO nanotips are very dense and predominatingly oriented along the c-axis with uniform size. The diameter of the bottom of nanotips is in the range of 40-60 nm and the length is ˜500 nm, giving an aspect ratio of ˜10:1. Inset of FIG. 1 (b) is the top view of ZnO nanotips. We have employed XRD measurement to characterize the crystalline orientation of the ZnO nanotips grown on Si substrate [J. Zhong et al. (2004), TMS & IEEE J. Elec. Mater, 33, p.654]. Only (0001) ZnO peak is present in the x-ray scan, indicating the c-axis orientation. Transmission electron microscope (TEM) measurement confirms the as-grown ZnO nanotips are single crystalline. Room temperature PL spectrum of these ZnO nanotips exhibits strong near band edge emission with negligible deep level emission. The presence of the dominant free excitonic emission corresponds to high purity and a low defect density of ZnO nanotips grown on Si substrate using MOCVD. The demonstration of ZnO nanotips growth on Si at a low temperature allows the integration of ZnO nanotip-based LEDs directly with Si, therefore with the Si IC technology.

Shown in FIG. 1(c) is a FESEM image of ZnO nanotips grown on glass substrate. The diameter of the bottom of nanotips is in the range of 40-60 nm and the height is ˜850 nm, giving an aspect ratio of ˜17: 1. The electron microscopy confirms the single crystal quality of the ZnO nanotips. High-resolution lattice images show a single crystalline nanoscale tip. Room temperature PL measurement confirms the good optical property of ZnO nanotips grown on glass [J. Zhong et al. (2003), Appl. Phys. Lett., 83, p.3401]. Our results show that single crystalline ZnO nanotips can be grown on cheap glass. The ZnO nanoLEDs fabricated on glass will offer a great advantage of low cost.

ZnO nanotips can also be grown on various metals, such as Au, Ti, etc. For instance, FIG. 1(d) shows a FESEM image of ZnO nanotips grown on gold. These nanotips grown on Au show similar morphology as those grown on Si and glass. They are also found to be single crystalline with good PL property [Hanhong Chen et al. (2004), Proceedings of SPIE, Volume: 5592-31]. Therefore, ZnO nanotips can be directly grown on top electrodes of an LED. This allows the direct integration of the passive ZnO nanotips on a conventional LED. This also allows the integration of ZnO p-n junction nanotips LEDs into programmable LED arrays.

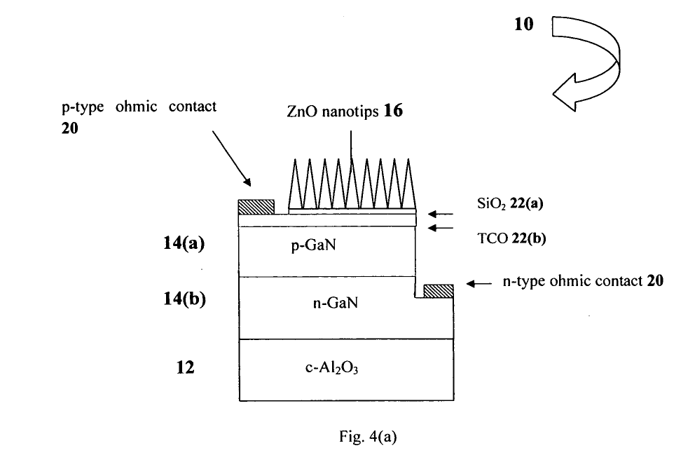

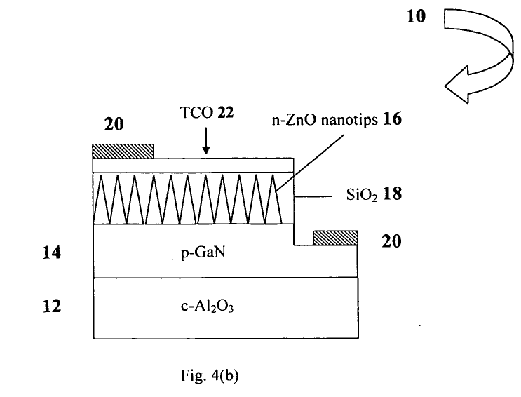

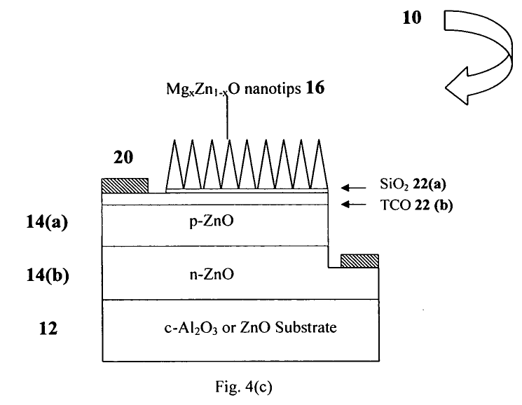

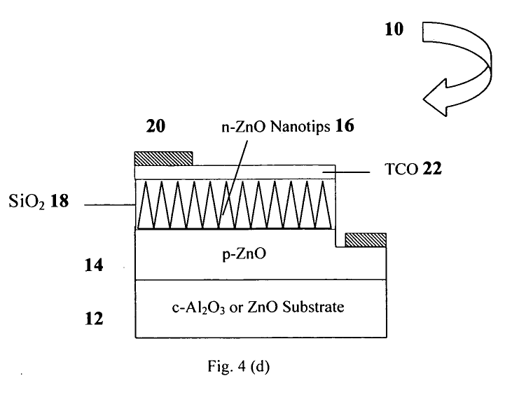

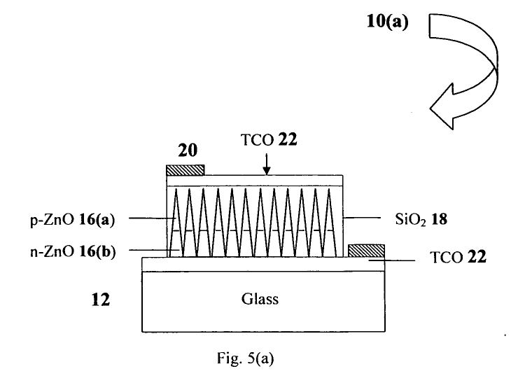

Referring now to FIGS. 4(a)-4(d), the present invention provides an LED 10 including: a substrate 12; and at least one semiconductor layer 14 of a ZnO or GaN film, or a ZnO and GaN p-n junction of film layers 14(a) and 14(b), which is deposited on substrate 12. LED 10 further includes a nanotip array 16 made from ZnO or its ternary compound (MgₓZn₁₋ₓO). Nanotip array 16 includes single crystalline nanotips. The nanotip array may include nanotips of undoped ZnO or its ternary compound. Alternatively, the nanotip array may include nanotips of doped ZnO or its ternary compound. The nanotip array includes substantially vertically aligned ZnO nanotips. The nanotips may be directly grown on ZnO or GaN semiconductor film layer 14, or indirectly grown on ZnO or GaN p-n junction film layers 14(a) and 14(b).

LED 10 also includes at least one transparent conductive oxide (TCO) layer 22 for electrical contact and light transmission. The TCO layer 22 may be Al- or Ga-doped ZnO or MgₓZn₁₋ₓO. Alternatively, the TCO layer 22 may be an Indium Tin Oxide (ITO) layer. LED 10 further includes a pair of metal pads 20 for electrodes and bonding. The metal pads may include a patterned ohmic metal.

The substrate depicted in FIGS. 4(a)-4(d) may be a single crystal with lattice parameters closely matched to ZnO. For example, in some embodiments, the substrate is a bulk single crystal ZnO substrate. Alternatively, the substrate may be a single crystal sapphire substrate.

In some embodiments, the at least one semiconductor film layer of ZnO or GaN is a single layer of p-type GaN, as shown in FIG. 4(b), or its ternary compound. Examples of ternary compounds of p-type GaN include, but are not limited to, p-InₓGa₁₋ₓN and p-AlₓGa₁₋ₓN.

In some further embodiments, the at least one semiconductor film layer of ZnO or GaN is a single layer of p-type ZnO, as shown in FIG. 4(d), or its ternary compound. Examples of ternary compounds of p-type ZnO include, but are not limited to, p-CdₓZn₁₋ₓO and p-MgₓZn₁₋ₓO.

With further reference to the embodiments shown in FIGS. 4(b) and 4(d), the nanotip array may be directly grown on a single semiconductor film layer 14 of p-type ZnO or p-type GaN. The LEDs may include an insulating material 18 deposited on top of the nanotips 16 directly grown on the single semiconductor film layer 14. This insulating material 18 fills the interstices of the nanotips. This insulating material may include a dielectric material, such as, but not limited to, SiO₂. The insulating material may be deposited using atomic layer deposition (ALD) or chemical vapor deposition (CVD), for example. A TCO layer 22 may be deposited on top of the insulator-filled nanotips after a top surface of the insulator-filled nanotips is etched, thereby being readied for ohmic contact. The TCO layer 22 deposited on the insulator-filled nanotips may be, for example, an ITO layer, Ga-doped ZnO, Ga-doped MgₓZn₁₋ₓO, Al-doped ZnO or Al-doped MgₓZn₁₋ₓO. The metal pads 20 shown may include an n-type metal contact to the TCO layer 22 deposited on the insulator-filled tips 16, and a p-type metal ohmic contact to the p-type ZnO or GaN film layer 14.

Referring now to FIGS. 4(a) and 4(c), in some embodiments, the at least one semiconductor film layer of ZnO or GaN includes two film layers of a p-n junction structure. An n-type layer is deposited directly on a substrate, and a p-type layer is deposited directly on the n-type layer. In some embodiments, the p-n junction structure is selected from, but not limited to, the following: a p-n junction of ZnO, a p-n junction of a ternary ZnO compound, a p-n junction of GaN or a p-n junction of a ternary GaN compound. A TCO layer 22 is deposited on top of a p-type ZnO or p-type GaN surface of the p-n junction structure, to form the top transparent and ohmic contact and to uniformly distribute the current. A SiO₂ layer 22(a) is deposited on part of the TCO layer 22(b). The ZnO nanotips 16 may be grown indirectly on the p-n junction structure. “Indirect” means that the ZnO nanotips are deposited on the patterned thin SiO₂ layer 22(a), which serves as a seed layer for ZnO nanotips growth. Such a configuration can fit the p-n junction with either the p- or n-layer on the top.

Referring now to the embodiment shown in FIG. 4(a), there is provided an LED 10 that includes a single crystal substrate 12 of c-plane sapphire (c-Al₂O₃). A p-n junction LED structure of GaN or its ternary compound is deposited on the substrate. This p-n junction structure includes a p-type GaN film layer 14(a) on top of an n-type GaN film layer 14(b). The LED in FIG. 4(a) further includes a layer of TCO 22(b), which is deposited on the p-type GaN film 14(a) to form a top electrical contact and to transmit light emission out. TCO layer 22 can be indium tin oxide (InₓSn₁₋ₓO), or a heavily n-type (such as Al or Ga) doped ZnO or MgₓZn₁₋ₓO transparent and conductive layer. A patterned SiO₂ layer 22(a) is deposited on part of TCO layer 22(b) to serve as a seed layer for ZnO or MgₓZn₁₋ₓO nanotips growth. ZnO or MgₓZn₁₋ₓO nanotips 16 are grown on top of the SiO₂ layer 22(a); and an ohmic metal pad is deposited on each of the TCO layer 22(a) and the n-type GaN film layer 14(b) for bonding.

However, other substrates with lattice parameters closely matched to GaN may be used. Nanotips 16 may be formed by self-assembled growth using techniques, such as MOCVD, where no nanopatterning or etching is required. In FIG. 4(a), ZnO nanotips 16 could have a feature size comparable to a half-wavelength of the internal optical wavelength. The strong surface scattering will randomize the angular distribution of photons inside the LED, and an enlarged equivalent escape cone and a higher light extraction for the trapped photons can be achieved. Finally, the metal contacts 20 are deposited to serve as the electrodes for ohmic contacts and bonding.

The embodiment shown in FIG. 4(b) is of an n-ZnO nanotips/p-GaN heterojunction LED. In this embodiment, n-type ZnO nanotips 16 are grown directly on a p-GaN film 14, and the p-GaN film 14 is deposited on top of a c-sapphire substrate 12. However, other lattice matched substrates (such as SiC) may be used. To fabricate the nanoLEDs shown in FIG. 4(b), first, n-type ZnO nanotips 16 are grown on an epitaxial p-GaN film/substrate using MOCVD. After the growth, an insulation material 18, such as SiO₂, is deposited on the nanotips 16 to fill interstices of the nanotips. The insulating material 18 can be deposited on the nanotips 16 using liquid-solid-phase and gas-phase fill-in techniques. In a liquid-solid-phase fill-in process, a spin-on-glass (SOG) solution is coated on the nanotips. In a gas-phase fill-in process, SiO₂ is deposited on the nanotips using atomic layer deposition (ALD) or plasma enhanced chemical vapor deposition (PECVD). The SiO₂ fills into the interstices of ZnO nanotips, and serves as an isolation layer. This step is followed either by a chemical mechanical polishing (CMP) process or selective dry etching to remove the SiO₂ layer on top of the nanotips for planarization, and to expose the tips of these ZnO nanostructures on the top for subsequent ohmic contacts formation. A p-GaN mesa area may be further defined using dry etching. The TCO layer 22 is deposited on the planarized and SiO₂-filled nanotip surface to serve as the top electrical contact layer, and to allow light emitting out. The LED shown in FIG. 4(b) also includes a pair of ohmic metal pads 20, a metal pad being deposited on the TCO layer 22 and on the p-GaN film layer 14.

With reference to FIG. 4(c), the present invention further provides an LED 10 that includes a single crystal substrate 12 with lattice parameters closely matched to ZnO; and a ZnO p-n junction LED structure, which is deposited on the substrate. The p-n junction LED structure includes a p-type ZnO film layer 14(a) on top of an n-type ZnO film layer 14(b). The ZnO p-n junction 14 is deposited directly on substrate 12, which can be a bulk single crystal ZnO for high crystalline quality homoepitaxial growth, or a c-plane sapphire crystal for heteroepitaxial growth. The ZnO p-n junction 14 is a type of device structure, which has been demonstrated recently [Kawasaki et al. (2005), Nature Mater. 4, p. 42]. The ZnO p-n junction 14 also can be in a different sequence. The LED in FIG. 4(c) also includes a layer of TCO 22(b) deposited on the p-type ZnO film layer 14(a), which serves as the electrical contact layer to gain uniform current flow, and at the same time, allows light transmission. The same as in the case of FIG. 4(a), Mg_{0.05}Zn_{0.95}O nanotips 16 act as a “roughened top surface”, and an integrated index close-matched transparent window, which reduce the internal light reflection and scatter the light outward. A SiO₂ layer (in several nm thickness) 22(a) is deposited on part of the TCO layer 22(b), serving as seeds for nanotips growth. MgₓZn₁₋ₓO (for example, Mg_{0.05}Zn_{0.95}O, i.e. Mg composition, x˜0.05) nanotips 16 are grown on top of the SiO₂ layer 22(a). Furthermore, this LED includes a pair of ohmic metal pads 20, a metal pad being deposited on each of the TCO layer 22(b) and on the n-type ZnO layer 14(b) to form electrodes for bonding. The ohmic contacts 20 are made by using the processing technology developed for ZnO epitaxial films at Rutgers University [H. Sheng et al. (2003), TMS & IEEE J. Elec. Mater, 32, p.935].

Referring now to FIG. 4(d), this invention further provides an LED that includes a single crystal substrate 12 with lattice parameters closely matched to ZnO; and a layer of p-type ZnO film 14 deposited on the substrate 12, which can be a bulk single crystal ZnO for homoepitaxy or c-plane sapphire crystal for heteroepitaxy. The LED also includes n-type ZnO or MgₓZn₁₋ₓO nanotips 16 that are directly grown on the p-type ZnO film 14. The same as in the case of FIG. 4(b), an insulating material 18 (e.g., SiO₂) is deposited on nanotips 16 to fill interstices between the nanotips. The top surface of the insulator-filled nanotips is etched to form a flat surface. A controlled etching process, such as chemical mechanism polishing (CMP), is carried out to planarize the surface and expose the tips for the electrical contact. Then, a TCO layer 22 (ITO or heavily n-type doped ZnO or MgₓZn₁₋ₓO) is deposited to form the top transparent conductive contact. Moreover, the LED includes a pair of ohmic metal pads 20, a metal pad being deposited on each of the TCO layer 22 and the p-type ZnO layer 14 to form electrodes for bonding.

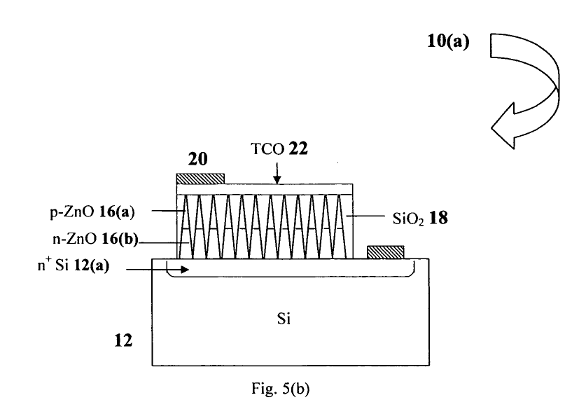

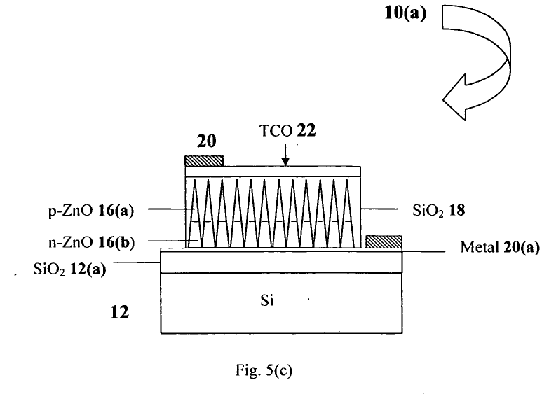

Referring now to FIGS. 5(a)-5(b), the present invention also provides an LED 10(a) that includes ZnO nanotips 16(a) and 16(b), which contain the p-n junction inside the nanotip. In particular, the present invention provides an LED that includes a substrate 12, such as glass or silicon; and an array of ZnO nanotips 16 that include a p-n junction in the nanotips, which may be of ZnO or MgₓZn₁₋ₓO, for example. The p-n junction in the nanotips 16 is made up of a p-ZnO portion 16(a) and an n-ZnO portion 16(b). The order of the p and n portions can be altered within the nanotip. The nanotips 16 are grown directly or indirectly on substrate 12.

The LEDs shown in FIGS. 5(a)-5(b) further include an insulating material 18 deposited on the nanotips 16(a) and 16(b) to fill the interstices between nanotips. The insulating material deposited on the nanotips may be a dielectric material, such as SiO₂. The top surface of the insulator-filled nanotips is etched to form a flat surface; and the TCO layer 22 that is deposited on the insulator-filled nanotips 16 serves as a top electrical contact for uniform current spreading and for light transmission. The TCO layer 22 on the nanotips may be an Al- or Ga-doped ZnO or MgₓZn₁₋ₓO layer. Alternatively, TCO layer 22 on the nanotips may be an ITO layer. The LEDs of FIGS. 5(a) and 5(b) also include a pair of metal pads. At least one of these metal pads is deposited on the TCO layer 22 on the nanotips 16(a).

Referring now to the embodiment shown in FIG. 5(a), there is provided an LED 10(a) that includes a substrate 12 of glass; a TCO layer 22 deposited on the glass substrate to serve as a bottom electrical contact; and p-n junction nanotips 16(a) and 16(b), the nanotips being grown on the TCO layer deposited on the glass substrate. This LED further includes a pair of metal pads 20, wherein a metal pad is deposited on each of the TCO layer on the nanotips and on the bottom TCO layer on the glass substrate to serve as electrodes for bonding. In some embodiments, the TCO layer deposited on the glass substrate is patterned, the nanotip array being deposited on the patterned TCO layer to form an integrated LED-array on low cost and transparent glass chips. As described above, ZnO nanotips p-n junction 16(a) and 16(b) is grown on top of TCO layer 22. The order of p and n portions can be altered within the nanotip. The insulating material 18 (SiO₂, etc.) fills in the interstices between the ZnO nanotips 16(a) and 16(b). The proper etching process, such as CMP, is performed to planarize the surface of the insulator-filled ZnO nanotips and expose the top of the tips. Another TCO layer 22 is deposited on the planarized surface to serve as the top transparent and conductive contact. A metal pad 20 is then deposited on each of the top and bottom TCO layers 22 for bonding.

Referring now to the embodiment shown in FIG. 5(b), there is provided an LED that includes a substrate 12 of Si. The Si substrate includes a doped n-type Si layer 12(a) on its surface. A ZnO nanotip array 16 containing a p-n homojunction 16(a) and 16(b) in the tips is directly grown on the Si substrate 12. The structure and processing are the same as shown in FIG. 5(a), except that the substrate 12 is now Si. The heavily doped Si layer 12(a) benefits to the bottom ohmic contact. As shown, a metal pad 20 is deposited on each of the TCO layer 22 on the nanotips and on the doped n-type Si layer 12(a) of the Si substrate to serve as electrodes for bonding. The process of TCO layer 22 and metal contacts 20 are the same as described in the case of FIG. 5(a). In some embodiments, the substrate of Si includes addressing circuits, the nanotip array being deposited on the substrate to form an integrated LED-array on Si chips. This configuration allows the integration of a ZnO nanostructure based UVAis emitter with Si IC technology. The array of ZnO nanoLED 10(a) can be integrated with the Si addressing circuits, to form the integrated and programmable ZnO nanoLED array on a Si chip.

Referring now to the embodiment shown in FIG. 5(c), there is provided an LED that includes a substrate 12, and an insulating film layer 12(a), which is deposited on top of the substrate 12. The substrate 12 can be a semiconductor, such as Si, SiC, etc. The insulating film 12(a) may be, but is not limited to, SiO₂. An insulting layer SiO₂ 12(a) is deposited or thermally grown on substrate 12, which is a silicon substrate. Then, a metal layer 20(a), such as Au, is deposited and patterned on top of insulating layer 12(a), serving as the bottom ohmic contact. A nanotip array 16, with the tips including a p-n junction made up of a p-ZnO portion 16(a) and an n-ZnO portion 16(b), is grown on top of metal layer 20(a). The insulating material 18 (SiO₂, etc.) fills in the interstices between the ZnO nanotips 16(a) and 16(b), followed by the etching process, such as CMP, to planarize the surface of the insulator-filled ZnO nanotips and expose the top of tips. A TCO layer 22 is deposited on the surface to serve as the top transparent electrode. A pair of metal pads 20 is then deposited on top TCO layer 22 and the bottom metal layer 20(a) for bonding. As such, the nanostructure of 16(a) and 16(b) is also the basic structure of a photodetector, which allows the integration of ZnO nanostructure-based UVvis emitters and photodetectors with Si-based MOS technology.

Although preferred embodiments of the present invention have been described herein with reference to the accompanying drawings, it is to be understood that the invention is not limited to those precise embodiments and that various other changes and modifications may be affected herein by one skilled in the art without departing from the scope or spirit of the invention, and that it is intended to claim all such changes and modifications that fall within the scope of the invention.

1. A Light Emitting Diode (LED) comprising:
a substrate;
at least one semiconductor film layer of ZnO or GaN deposited on said substrate;
an array of nanotips made from ZnO or its ternary compound, said nanotip array being grown either directly or indirectly on a surface of said at least one film layer;
at least one transparent and conductive oxide (TCO) layer deposited on said at least one film layer or said nanotip array; and
a pair of metal pads, a metal pad of said pair being deposited on each of said TCO layer and said at least one film layer.

2. The LED of claim 1, wherein said substrate is a bulk single crystal ZnO substrate.

3. The LED of claim 1, wherein said substrate is a single crystal sapphire substrate.

4. The LED of claim 1, wherein said substrate is a crystal with lattice parameters closely matched to ZnO.

5. The LED of claim 1, wherein said at least one film layer is of single layer p-type GaN or its ternary compound.

6. The LED of claim 5, wherein said ternary compound of p-type GaN is p-InₓGa₁₋ₓN or p-AlₓGa₁₋ₓN.

7. The LED of claim 1, wherein said at least one film layer is of single layer p-type ZnO or its ternary compound.

8. The LED of claim 7, wherein said ternary compound of p-type ZnO is p-CdₓZn₁₋ₓO and p-MgₓZn₁₋ₓO.

9. The LED of claim 1, wherein said nanotip array comprises single crystalline nanotips.

10. The LED of claim 1, wherein said nanotip array comprises substantially vertically aligned nanotips.

11. The LED of claim 1, wherein said nanotip array comprises nanotips of doped ZnO or its ternary compound.

12. The LED of claim 1, wherein said nanotip array comprises nanotips of undoped ZnO or its ternary compound.

13. The LED of claim 1, wherein said TCO layer is Al- or Ga-doped ZnO or MgₓZn₁₋ₓO.

14. The LED of claim 1, wherein said TCO layer is an Indium Tin Oxide (ITO) layer.

15. The LED of claim 1, wherein said metal pads comprise a patterned ohmic metal to serve as electrodes for bonding.

16. The LED of claim 1, wherein said array of nanotips is directly grown on a single semiconductor film layer.

17. The LED of claim 16, further comprising an insulating material deposited on top of said nanotips to fill interstices of said nanotips, said TCO layer being deposited on said insulator-filled nanotips.

18. The LED of claim 17, wherein a top surface of said insulator-filled nanotips is etched, thereby being readied for ohmic contact.

19. The LED of claim 17, wherein said insulating material deposited on said nanotips is a dielectric material.

20. The LED of claim 17, wherein said insulating material deposited on said nanotips is SiO₂.

21. The LED of claim 17, wherein said insulating material is deposited using one of the groups consisting of atomic layer deposition (ALD), chemical vapor deposition (CVD), and spin-on-glass technology.

22. The LED of claim 17, wherein said TCO layer deposited on said insulator-filled nanotips is Ga- or Al-doped ZnO or MgₓZn₁₋ₓO.

23. The LED of claim 17, wherein said TCO layer deposited on said insulator-filled nanotips is an Indium Tin Oxide (ITO) layer.

24. The LED of claim 17, wherein said metal pads include an n-type metal contact to said TCO layer and a p-type metal ohmic contact to semiconductor film layer.

25. The LED of claim 1, wherein said at least one film layer comprises two film layers of a p-n junction structure, with an n-type layer being deposited directly on said substrate, and a p-type layer being deposited directly on said n-type layer.

26. The LED of claim 25, wherein said p-n junction structure is selected from the group consisting of a p-n junction of ZnO, a p-n junction of a ternary ZnO compound, a p-n junction of GaN and a p-n junction of a ternary GaN compound.

27. The LED of claim 25, said ZnO nanotip array being grown indirectly on said p-n junction structure.

28. The LED of claim 27, wherein said TCO layer is deposited on top of a p-type ZnO or p-type GaN surface of said p-n junction structure.

29. The LED of claim 28, further comprising a SiO₂ layer deposited on top of said TCO layer, said ZnO nanotips being grown on said SiO₂ layer.

30. The LED of claim 1, comprising:
a single crystal substrate with lattice parameters closely matched to GaN;
a p-n junction LED structure of GaN or its ternary compound deposited on said substrate,
said p-n junction LED structure comprising a p-type GaN film layer on top of an n-type GaN film layer;
a layer of TCO deposited on said p-type GaN film to form a top electrical contact;
a patterned SiO₂ layer deposited on part of said TCO layer;
ZnO or MgₓZn₁₋ₓO nanotips grown on top of said SiO₂ layer; and
a pair of ohmic metal pads, a metal pad of said pair being deposited on each of the TCO layer and the n-type GaN film layer to form electrodes for bonding.

31. The LED of claim 30, wherein said single crystal substrate is a c-plane sapphire substrate.

32. The LED of claim 1, comprising:
a single crystal substrate with lattice parameters closely matched to GaN;
a layer of p-type GaN film deposited on said substrate;
n-type ZnO or MgₓZn₁₋ₓO nanotips directly grown on said p-type GaN film layer;
an insulation material deposited on said nanotips to fill interstices of said ZnO nanotips, a top surface of said insulator-filled nanotips being planarized;
a TCO layer deposited on top of said planarized top surface of said insulator-filled ZnO nanotips to serve as a top electrical contact; and
a pair of ohmic metal pads, a metal pad of said pair being deposited on each of said TCO layer and said p-GaN film layer to form electrodes for bonding.

33. The LED of claim 32, wherein said single crystal substrate is a c-plane sapphire substrate.

34. The LED of claim 1, comprising:
a single crystal substrate with lattice parameters closely matched to ZnO;
a ZnO p-n junction LED structure deposited on said substrate, said p-n junction LED structure comprising a p-type ZnO film layer on top of an n-type ZnO film layer;
a layer of TCO deposited on said p-type ZnO film layer;
a SiO₂ layer deposited on part of said TCO layer;
ZnO or MgₓZn₁₋ₓO nanotips grown on top of said SiO₂ layer; and
a pair of ohmic metal pads, a metal pad of said pair being deposited on each of said TCO layer and said n-type ZnO layer to form electrodes for bonding.

35. The LED of claim 34, wherein said single crystal substrate is selected from the group consisting of c-plane sapphire and c-plane ZnO.

36. The LED of claim 1, comprising:
a single crystal substrate with lattice parameters closely matched to ZnO;
a layer of p-type ZnO film deposited on said substrate;
n-type ZnO or MgₓZn₁₋ₓO nanotips directly grown on said p-type ZnO film;
an insulating material deposited on said nanotips to fill interstices of said nanotips, a top surface of said insulator-filled nanotips being etched to form a flat surface;
a TCO layer deposited on said flat top surface of said insulator-filled nanotips to serve as a top electrical contact; and
a pair of ohmic metal pads, a metal pad of said pair being deposited on each of said TCO layer and said p-type ZnO layer to form electrodes for bonding.

37. The LED of claim 36, wherein said single crystal substrate is selected from the group consisting of c-plane sapphire and c-plane ZnO.

38. A Light Emitting Diode (LED) comprising:
a substrate;
an array of ZnO nanotips comprising a p-n junction in said nanotips made up of a p-ZnO portion and an n-ZnO portion, said nanotips being grown directly or indirectly on said substrate;
an insulating material deposited on said nanotips to fill interstices of said nanotips, a top surface of said insulator-filled nanotips being etched to form a flat surface;
a TCO layer deposited on said flat top surface of said insulator-filled nanotips to serve as a top electrical contact; and
a pair of metal pads, at least one of said metal pads being deposited on said TCO layer on said nanotips.

39. The LED of claim 38, wherein said substrate is glass.

40. The LED of claim 38, wherein said substrate is silicon.

41. The LED of claim 38, wherein said nanotip array is of ZnO or MgₓZn₁₋ₓO nanotips.

42. The LED of claim 38, said n-ZnO portion of said p-n junction of said nanotips being in direct or indirect contact with said substrate.

43. The LED of claim 38, wherein said insulating material deposited on said nanotips is a dielectric material.

44. The LED of claim 38, wherein said insulating material deposited on said nanotips is SiO₂.

45. The LED of claim 38, wherein said TCO layer is an Al- or Ga-doped ZnO or MgₓZn₁₋ₓO layer.

46. The LED of claim 38, wherein said TCO layer is an ITO layer.

47. The LED of claim 38, further including a TCO layer deposited on said substrate, said nanotips being grown on top of said TCO layer deposited on said substrate.

48. The LED of claim 38, comprising:
a substrate of glass; and
a TCO layer deposited on said glass substrate, said p-n junction nanotips being grown on said TCO layer deposited on said glass substrate;
wherein a metal pad of said pair of metal pads is deposited on each of said TCO layer on said nanotips and said TCO layer on said glass substrate to serve as electrodes for bonding.

49. The LED of claim 48, wherein said TCO layer deposited on said glass substrate is patterned, said nanotip array being deposited on said patterned TCO layer to form an integrated LED-array on low cost and transparent glass chips.

50. The LED of claim 38, comprising:
a substrate of Si including a doped n-type Si layer on its surface, said p-n junction nanotips being grown directly on said Si substrate;
wherein a metal pad of said pair of metal pads is deposited on each of said TCO layer on said nanotips and said doped n-type Si layer of said Si substrate to serve as electrodes for bonding.

51. The LED of claim 50, wherein said substrate of Si includes addressing circuits, said nanotip array being deposited on said substrate to form an integrated LED-array on Si chips.

52. The LED of claim 38, comprising:
an insulating substrate or a substrate including an insulating film; and
a metal layer on said substrate serving as a bottom electrical contact layer,
a metal pad of said pair of metal pads being deposited on each of said TCO layer on said nanotips and said metal layer to serve as electrodes for bonding.

53. The LED of claim 52, wherein said metal layer is patterned, said nanotip array being deposited on said patterned metal layer to form an integrated LED-array on insulating substrate chips.
